(19) United States
(12) Patent Application Publication
(10) Pub. No.: US 2010/0025792 A1
(43) Pub. Date: Feb. 4, 2010

(54) IMAGE PICKUP APPARATUS, MANUFACTURING METHOD THEREOF, AND MOBILE TERMINAL

(75) Inventors: Kiyohiko Yamada, Kanagawa (JP); Makoto Imai, Kanagawa (JP); Hiroshi Nishizawa, Kanagawa (JP)

Correspondence Address: MCDERMOTT WILL & EMERY LLP, 600 13TH STREET, NW, WASHINGTON, DC, 20005-3096, US

(73) Assignee: PANASONIC CORPORATION, Osaka (JP)

(21) Appl. No.: 12/521,092

(22) PCT Filed: Jan. 9, 2008
(86) PCT No.: PCT/JP2008/050143

§ 371 Date: Jun. 24, 2009

(30) Foreign Application Priority Data
Jan. 9, 2007 (JP) 2007-001677
Jan. 9, 2007 (JP) 2007-001678

(51) Int. Cl. H01L 31/0232; H01L 21/50

(52) U.S. Cl. 257/432; 438/65; 257/E31.127; 257/E21.499

(57) ABSTRACT

Degradation of a picked-up image quality occurs because of entry or a move of dust in the internal space of an image pickup apparatus. An image pickup apparatus for decreasing degradation of the image quality by capturing dust is provided. An image pickup apparatus 18 having a lens block 19 containing a lens 2, a semiconductor image pickup device 4 mounted on one face of a board 1, and a translucent member 5 mounted on an opposite face is characterized in that it has a gap 24 to allow a solution 23 with an adhesive dissolved to penetrate outside an optically effective range outside the space surrounded by the semiconductor image pickup device 4, the translucent member 5, and the board 1.

### TECHNICAL FIELD

This invention relates to an image pickup apparatus, a manufacturing method thereof, and a mobile terminal, and in particular to a small image pickup apparatus adopting a semiconductor image pickup device and a mobile telephone adopting the image pickup apparatus.

### BACKGROUND ART

An image pickup apparatus is implemented by mounting a semiconductor image pickup device chip on a mount board and attaching a lens thereon. The light guide space between the semiconductor image pickup device and the lens is extremely important on implementation and if dust is deposited or a flaw occurs in the light guide space, degradation of the image quality is incurred, and thus various measures are proposed.

For example, an image pickup apparatus is proposed wherein a spacer member having adhesion on an end face is placed in a space for fixing a semiconductor image pickup device, and dust is adhered to the exposed end face of the spacer, thereby preventing dust from being deposited on the semiconductor image pickup device so as not to affect the image quality (patent document 1).

A method is also proposed wherein hold means capable of holding dust is provided in the light guide space between a semiconductor image pickup device and a lens, and dust is held on the hold means, thereby preventing dust from being deposited on the lens, the light reception surface of the image pickup device, an optical filter, etc., to prevent degradation of the image quality (patent document 2).

Further, if a filler of an adhesive agent is put on a semiconductor image pickup device, a flaw occurs and a correction can be made to the flaw by complementation from ambient pixels depending on the size of the flaw, as disclosed in patent document 3 (patent document 3).

Patent document 1: JP-2005-217546A (page 4, FIG. 6)

Patent document 2: JP-2005-316127A (page 6, FIG. 2)

Patent document 3: JP-2004-327914A (page 6, FIG. 6)

### DISCLOSURE OF THE INVENTION

### Problems to be Solved by the Invention

By the way, in the image pickup apparatus described in patent document 1, it is assumed that the spacer is effective for capturing dust in the space partitioned by the semiconductor image pickup device and the optical filter, but it is known that the dust in the space has a size as much as the pixel size and affects output from the image pickup device and thus pixel output lowers and a flaw occurs. Therefore, it is found that it is more effective to assemble the apparatus in a sufficiently clean environment than to capture dust because the size of the dust to be captured is very small as much as several μm. There is a possibility of occurrence of degradation of the image quality because of slight dropping off of the adhesive agent having adherence property caused by stress of heat shock, vibration, shock, etc. Further, since an adhesive region is formed in the plane of the spacer, it is feared that dust may enter from an area where no spacer is provided. Interposition of the spacer leads to an increase in the number of parts, variations in optical distance are easily caused to occur, and fluctuation in the optical characteristic may be unable to be avoided.

In the image pickup apparatus described in patent document 2, hold means capable of holding dust is provided in the light guide space between the semiconductor image pickup device and the lens for holding dust on the hold means. However, the size of dust degrading the image quality is very small as much as the pixel size on the surface of the semiconductor image pickup device, but is larger as the dust is more distant from the semiconductor image pickup device, on the optical filter or the lens. This means that the size of the dust to be held varies largely depending on the distance from the semiconductor image pickup device. Since the size range of the dust to be captured becomes wide, it is necessary to stably capture and hold a wide size range of dust. Thus, it is necessary to be able to change the size of dust that can be held on the hold means or to be able to hold a sufficiently wide size range of dust and flexibility of material selection and design selection is low; this is a problem.

Although a method of removing a flaw by correction is also proposed as in patent document 3, once deposited material may move inside and to attempt to provide a stable characteristic over a long term, it is desirable that dust should be excluded from an effective area as much as possible.

The invention is intended for solving the above-described problems and it is an object of the invention to provide an excellent small image pickup apparatus capable of decreasing image quality degradation caused by deposition or a move of dust and enhancing flexibility of design and a mobile terminal adopting the image pickup apparatus.

### Means For Solving the Problems

To accomplish the object, an image pickup apparatus of the invention is characterized by that a semiconductor image pickup device is installed on a board, and a translucent member and a lens are disposed with a spacing of an optical space within an image pickup area of the semiconductor image pickup device and that a gap to allow an adhesive-contained liquid to penetrate is provided outside a space surrounded by the semiconductor image pickup device, the translucent member and the board in the optical space, so that an adhesive area can be formed outside an optically effective area where an image can be picked up in the image pickup area.

According to this configuration, the dust to be captured is captured outside the optically effective range and thus the captured dust does not optically affect the image quality. The size of captured dust becomes large as compared with the space where the light reception face of the semiconductor image pickup device exists and small dust does not affect the image quality if it cannot be captured; since the adhesive need not capture minute dust, a wide choice of options of adhesive is provided. Further, dropping off of the adhesive agent itself caused by vibration or shock is also possible, but if dust is not larger dust, the image quality is not affected and thus reliability is enhanced. In addition, an adhesive area can be formed without attaching another member such as a spacer, so that variations in the optical characteristic are not caused to occur. The optical space mentioned here refers to an area where an optical path can be formed.

The invention contains the image pickup apparatus described above wherein the semiconductor image pickup device is mounted on one face of the board, and the translucent member is mounted on the other face of the board, and in addition a lens block carrying the lens is placed on the board with a predetermined spacing from the translucent member, and wherein the gap to allow the adhesive-contained liquid to penetrate is provided in an interface between the board and the lens block.

According to this configuration, further a gap to allow a solution with an adhesive dissolved to penetrate is included and thus the adhesive can be given outside the optically effective range after the image pickup apparatus is assembled, so that flexibility of the process improves and the workability is good; since the adhesive area is formed so as to fill the gap, hermeticity also improves and dust can be made fine in the adhesive area, so that higher reliability can be provided.

The invention contains the image pickup apparatus described above wherein the gap includes an injection part having a larger opening than the gap to inject the solution.

According to this configuration, when an adhesive is injected outside the optically effective range, the workability improves because the larger opening than the gap is provided.

The invention contains the image pickup apparatus described above wherein the adhesive area is formed of an applied film containing an adhesion component.

According to this configuration, the workability improves and the thickness is an almost no thickness, so that the optical distance can be decreased. According to this configuration, adhesion can be provided outside the optically effective range.

The image pickup apparatus of the invention is characterized by that the semiconductor image pickup device is installed on the board, and the translucent member and the lens are disposed with a spacing of an optical space in the image pickup area of the semiconductor image pickup device, and that the adhesive area is formed at least in a part of the area surrounding the optically effective area where the image can be picked up in the image pickup area outside the space surrounded by the semiconductor image pickup device, the translucent member, and the board in the optical space.

According to this configuration, the dust to be captured is captured outside the optically effective range and thus the captured dust does not optically affect the image quality. Since the adhesive area is formed outside the space surrounded by the semiconductor image pickup device, the translucent member, and the board and thus the size of captured dust becomes large as compared with the space where the light reception face of the semiconductor image pickup device exists and small dust does not affect the image quality if it cannot be captured; since the adhesive need not capture minute dust, a wide choice of options of adhesive is provided and design becomes flexible. Further, dropping off of the adhesive agent itself caused by vibration or shock is also possible, but if dust is not larger dust, the image quality is not affected and thus reliability is enhanced. In addition, an adhesive area can be formed without attaching another member such as a spacer, so that variations in the optical characteristic are not caused to occur. The optical space mentioned here refers to an area where an optical path can be formed.

The invention contains the image pickup apparatus described above wherein the semiconductor image pickup device is mounted on one face of the board and the translucent member is mounted on the other face of the board, and in addition a lens block carrying the lens is placed on the board with a predetermined spacing from the translucent member.

The invention contains the image pickup apparatus described above wherein the adhesive area is formed of an applied film containing an adhesion component.

According to this configuration, the workability improves and the thickness is an almost no thickness, so that the optical distance can be decreased. According to this configuration, adhesion can be provided outside the optically effective range.

The invention contains the image pickup apparatus described above wherein the adhesive area is disposed at least in a part of an abutment area of the lens block with the board.

According to this configuration, the adhesive area is disposed at least in a part of the abutment area of the lens block and the board and thus the size of captured dust becomes large as compared with the space where the light reception face of the semiconductor image pickup device exists and small dust does not affect the image quality if it cannot be captured; since the adhesive need not capture minute dust, a wide choice of options of adhesive is provided. Further, dropping off of the adhesive agent itself caused by vibration or shock is also possible, but if dust is not larger dust, the image quality is not affected and thus reliability is enhanced. Since the cleanness in the lens assembling step can be lowered, it is made possible to assemble the lens in an environment of a simple clean booth, etc., rather than an expensive clean room and it is made possible to reduce the cost and also decrease the depreciation expense involved in the clean room, etc.

The invention contains the image pickup apparatus described above wherein the adhesive area is disposed in a whole circumference surrounding the semiconductor image pickup device, of the abutment area of the lens block with the board.

The invention contains the image pickup apparatus described above wherein the adhesive area is provided at a position inward by a predetermined width from an outer end of the board and is disposed along an outer periphery of the board.

According to this configuration, if the viscosity of the applied agent to form the adhesive area is low, the applied agent does not protrude and the adhesive area can be well formed.

The invention contains the image pickup apparatus described above wherein the adhesive area is projected outward so as to have a spread part at least in a part of the outer periphery.

According to this configuration, it becomes easy to fill the adhesive to form the adhesive area and in addition, external dust can be captured efficiently.

The invention contains the image pickup apparatus described above wherein the adhesive area is filled into a recess part provided in the board or the lens block.

According to this configuration, the area to form the adhesive area is defined with good accuracy and is formed efficiently without protrusion.

If the gap is provided in the lens block, the lens block needs only to be changed for an image pickup apparatus different in the lens specifications, so that it is made possible to share the board

The invention contains the image pickup apparatus described above wherein the translucent member is an optical filter of a layered product of a plurality of dielectrics.

According to this configuration, the optical filter can be implemented by laying up thin films and thus it is effective for slimming down the image pickup apparatus.

The invention contains the image pickup apparatus described above wherein the board is a stereoscopic board having a placement part for placing the semiconductor image pickup device thereon.

According to this configuration, the semiconductor image pickup device is positioned and the lens block is attached with the stereoscopic board as the reference, so that work of intricate optical axis alignment, etc., can be decreased.

The invention contains the image pickup apparatus described above wherein the lens, the translucent member, the board, and the semiconductor image pickup device are placed in this order from the subject side along the optical axis and the adhesive area is formed at least in a part of the abutment area of the lens with the translucent member.

It is desirable that the solution in which the adhesive is dissolved should be volatile. According to this configuration, tack shortage is made possible because it is not necessary to enter in a drying stove and continuous process rather than batch treatment can be executed.

The invention contains the image pickup apparatus described above wherein the adhesive area is an area for fixing the lens block to the board.

According to this configuration, an adhesive is filled into the area where a gap essentially occurs, whereby the gap is filled and the adhesive area having the dust capturing effect can be formed, so that it is made possible to form a highly reliable image pickup apparatus without fluctuation of the optical distance.

A manufacturing method of the above-described image pickup apparatus is characterized by that it includes the steps of providing the lens, the semiconductor image pickup device, the translucent member, and the board; and mounting the translucent member, the semiconductor image pickup device, and the lens on the board.

The manufacturing method of the image pickup apparatus of the invention is characterized by that it includes the steps of providing the lens, the semiconductor image pickup device, the translucent member, and the board; and mounting the translucent member, the semiconductor image pickup device, and the lens on the board and after the step of mounting the lens, the step of filling an adhesive-contained liquid into a gap so as to surround an optically effective area where an image can be picked up in the image pickup area outside the space surrounded by the semiconductor image pickup device, the translucent member, and the board.

According to this step, after the translucent member and the semiconductor image pickup device are mounted on the board in a highly clean environment, the lens can be assembled, so that the cleanness in the lens assembling step can be lowered and thus it is made possible to assemble the lens in an environment of a simple clean booth, etc., rather than an expensive clean room and it is made possible to reduce the cost and also decrease the depreciation expense involved in the clean room, etc. After the lens block is mounted on the board, a solution with an adhesive dissolved is penetrated into the gap of the board and the lens block, so that the mounting strength of the lens block and the board is not lowered.

The manufacturing method of the image pickup apparatus of the invention includes the steps of providing a lens block incorporating the lens, the semiconductor image pickup device, the translucent member, and the board, mounting the translucent member and the semiconductor image pickup device on the board, mounting the lens block on the board, and penetrating a solution with an adhesive dissolved into a gap between the board and the lens block.

According to this configuration, an adhesive is filled into the gap occurring between the lens block and the board, thereby capturing dust and removing the gap, so that it is made possible to provide a highly reliable image pickup apparatus without incurring fluctuation of the optical distance.

In the manufacturing method of the image pickup apparatus of the invention, the penetrating step includes a step of filling into the gap a solution in which an adhesive is dissolved in a volatile solution.

According to this configuration, an adhesive can be filled into a small gap with good workability. As the adhesive, an adhesive dissolved in a volatile solution is easy to handle. Preferably, the viscosity of the adhesive solution is about 100 cp.

In the manufacturing method of the image pickup apparatus of the invention, the penetrating step includes a step of filling and penetrating the solution from two opposed directions.

According to this configuration, the solution can be filled into all areas with good workability. It is desirable that the opening should be provided on the long side; accordingly, the solution can also be penetrated into the long side with good workability.

In the manufacturing method of the image pickup apparatus of the invention, the image pickup apparatus is assembled by executing the step of applying an adhesive to the board and the step of mounting the lens after the step of mounting the semiconductor image pickup device on the board.

According to this configuration, after the translucent member and the semiconductor image pickup device are mounted on the board in a highly clean environment, the lens can be assembled, so that the cleanness in the lens assembling step can be lowered. Therefore, it is made possible to assemble the lens in an environment of a simple clean booth, etc., rather than an expensive clean room and it is made possible to reduce the cost and also decrease the depreciation expense involved in the clean room, etc.

The manufacturing method of the invention includes the step of applying an adhesive on a part other than an optically effective range of the lens prior to the step of mounting the lens.

According to this method, an adhesive is applied outside the optically effective range of the lens prior to the step of mounting the lens, whereby the adhesive can be applied singly, so that the process flexibility in the mounting step improves.

The invention is characterized by that the above-described image pickup apparatus is adopted with a mobile terminal.

According to this configuration, the possibility that degradation of the image quality of the image pickup apparatus may occur in the mobile terminal can be decreased, so that the reliability of the mobile terminal can be improved.

The invention is characterized by that the image pickup apparatus manufactured by the above-described manufacturing method is adopted with a mobile terminal.

According to this configuration, the possibility that degradation of the image quality of the image pickup apparatus may occur in the mobile terminal can be decreased, so that the reliability of the mobile terminal can be improved.

### Advantages of the Invention

Since dust in the image pickup apparatus is captured outside the optically effective range, degradation of the image quality can be prevented and a highly reliable image pickup apparatus can be realized. After the lens block, etc., is mounted, a filler can be filled into a gap to form an adhesive area, so that there are also advantages of forming an adhesive area in a minuter gap and filling the gap.

### BRIEF DESCRIPTION OF THE DRAWINGS

FIG. 1 is a perspective view of an image pickup apparatus according to a first embodiment of the invention.

FIG. 2 is a sectional view of the image pickup apparatus taken on line X-X in FIG. 1.

FIG. 3 is a conceptual drawing to show the relationship between dust and a light flux in the image pickup apparatus.

FIG. 4 is a characteristic drawing to show the effect of dust in each portion in the image pickup apparatus.

FIG. 5 is a sectional view to show applied positions of an adhesive in the image pickup apparatus.

FIG. 6 is a sectional view to describe an applying method of an adhesive.

FIG. 7 is a main part plan view to describe an adhesive flow and is a sectional view taken on line Y-Y.

FIG. 8 is a flowchart to show a manufacturing process of the image pickup apparatus.

FIG. 9 is a characteristic drawing to show the effect of dust in each portion in an image pickup apparatus according to a third embodiment of the invention.

FIG. 10 is a flowchart to show a manufacturing process of the image pickup apparatus.

FIG. 11 is an external view of a mobile telephone according to the first embodiment of the invention.

### DESCRIPTION OF REFERENCE NUMERALS

1 Stereoscopic board

2, 2a, 2b Lens

3 Diaphragm

4 Semiconductor image pickup device

5 Optical filter

6, 6A, 6B Adhesive

7 Pedestal section

7a Terminal part

7c Wiring pattern

8 Image pickup apparatus

9 Sealing compound

10 Opening

11 Partition wall

14 Metal foil

15 FPC

15a Land

16 Soldering

17 Lens-barrel section

20 Lens holder

19 Lens block

20 Lens holder

21 Lens base

22 Injection means

23 Solution containing an adhesive

24 Gap

25 Adhesive agent

30 Mobile telephone

31 Upper housing

32 Lower housing

33 Loudspeaker

34 Display screen

35 Hinge

36 Antenna

37 Input key

38 Image pickup apparatus

39 Microphone

### BEST MODE FOR CARRYING OUT THE INVENTION

### First Embodiment

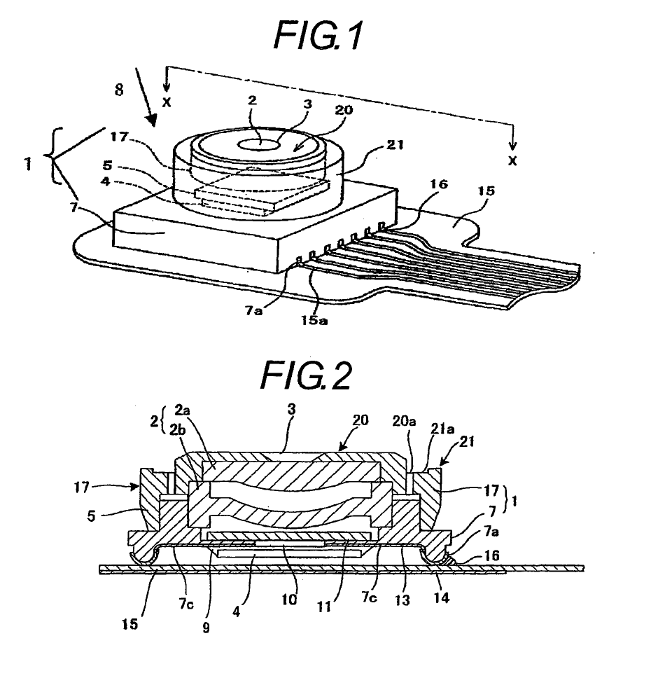

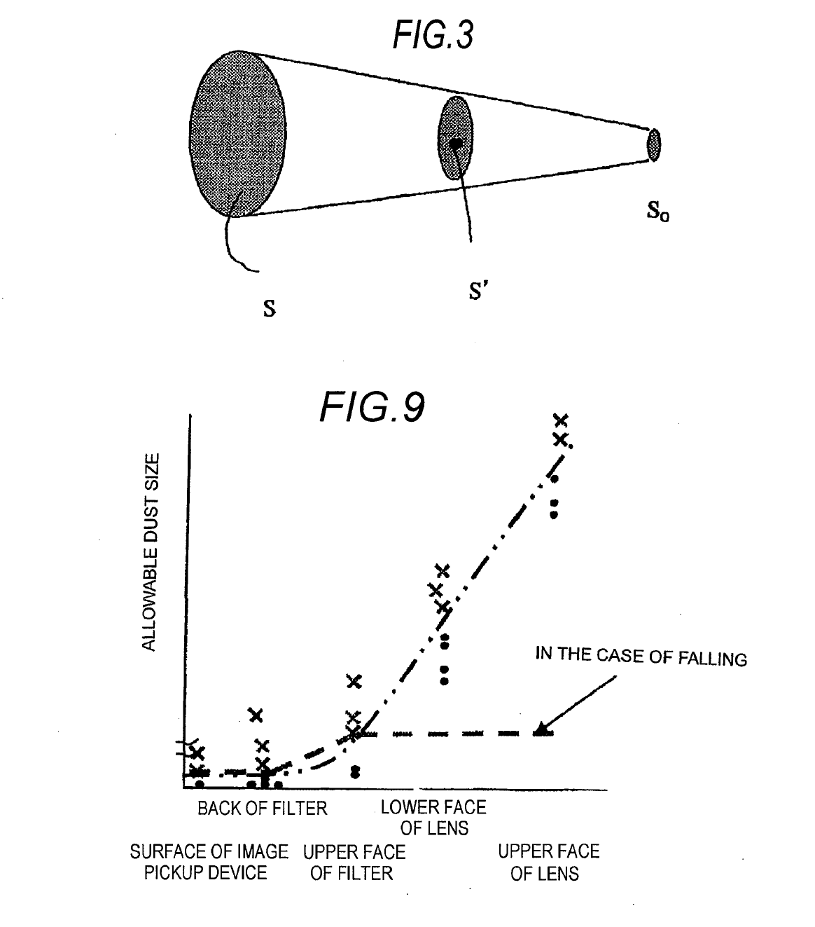

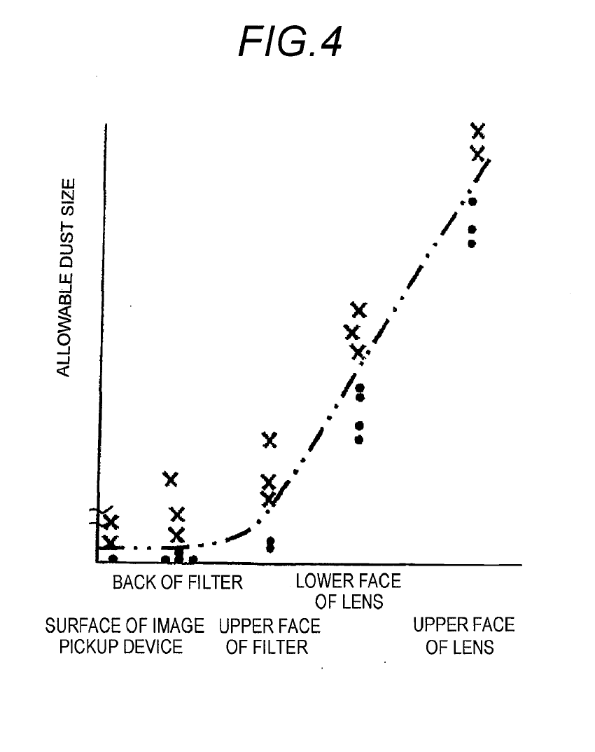

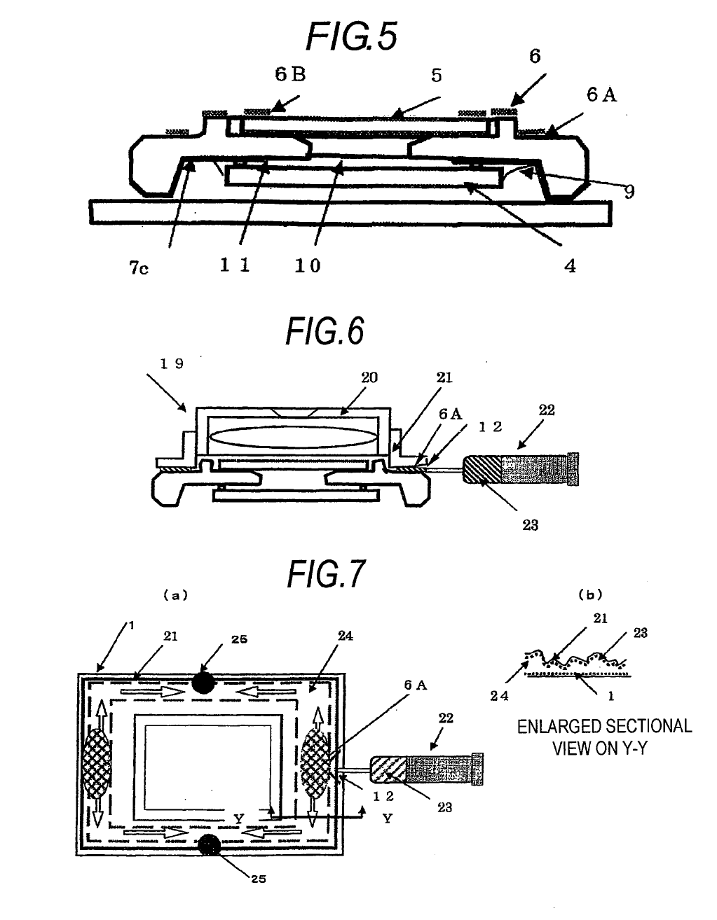

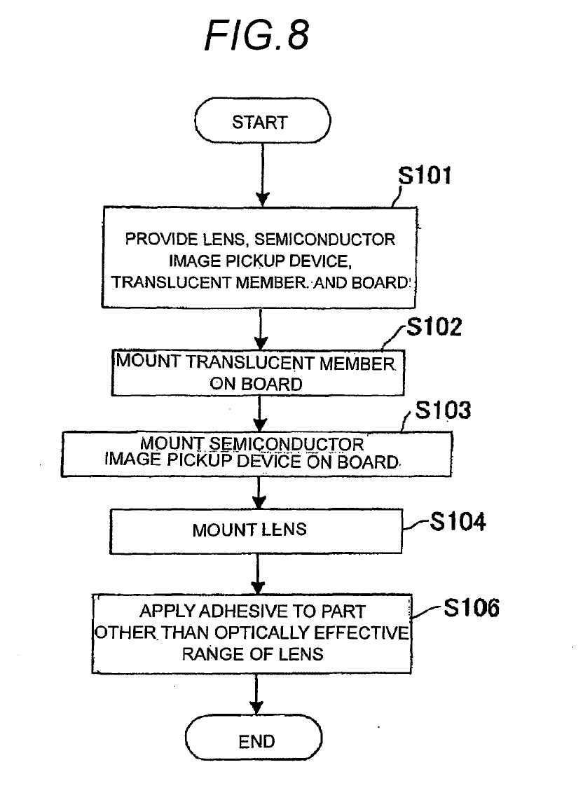

Embodiments of the invention will be discussed in detail with reference to the accompanying drawings. FIG. 1 is a perspective view of an image pickup apparatus according to a first embodiment of the invention, FIG. 2 is a sectional view of the image pickup apparatus taken on line X-X in FIG. 1, FIG. 3 is a conceptual drawing of the relationship between dust and a light flux, FIG. 4 is a characteristic drawing to show the effect of dust in each portion, FIG. 5 is a sectional view to show applying positions of an adhesive, FIG. 6 is a sectional view to describe an applying method of an adhesive, FIG. 7 (a) is a main part plan view to describe an adhesive flow, FIG. 7 (b) is a sectional view taken on line Y-Y in FIG. 7 (a), and FIG. 8 is a flowchart to show a manufacturing process of the image pickup apparatus.

The image pickup apparatus according to the embodiment is characterize in that a semiconductor image pickup device 4 and an optical filter 5 as a translucent material are placed on one face of a stereoscopic board 1 and further a lens 2 (lens block 19) built in a lens holder 20 is placed on the other face of the stereoscopic board 1, and that a gap to allow an adhesive-contained liquid to penetrate is provided outside the space surrounded by the semiconductor image pickup device, the translucent member, and the board so that an adhesive area can be formed outside an optically effective area where an image can be picked up in the above-mentioned image pickup area; the area surrounding the optically effective area where an image can be picked up in the image pickup area of the semiconductor image pickup device forms an adhesive area by filling an adhesive into the gap formed in an interface between the lens block 19 and the board 1 after placing the lens block 19 on the board 1. In the lens placement face, the area surrounding the optically effective area where an image can be picked up in the image pickup area of the semiconductor image pickup device forms an adhesive area provided by applying an adhesive 6, 6A, 6B.

This adhesive area is provided at a position inward by a predetermined width from the outer end of the stereoscopic board 1 and is disposed along the outer periphery of the stereoscopic board so as to block entry of external dust.

In FIG. 1, an image pickup apparatus 8 is formed of the stereoscopic board 1 made up of a pedestal section 7 and a lens-barrel section 17 provided thereon. PPA (polyphthalamide resin), etc. is used for the stereoscopic board 1, and it is made black to prevent transmission of external light. A terminal part 7a to connect to the outside is provided on the outside of the pedestal section 7 and is connected to a connection land 15a formed on a flexible printed circuit board (hereinafter, FPC) 15 by soldering 16. A resin lens 2 fitted into the lens holder 20 is placed in the lens-barrel section 17. The lens 2 built in the lens holder 20, a lens base 21 is called lens block 19. In this way, the lens 2 is made up of two aspheric lenses (hereinafter, lenses) 2a and 2b different from each other in optical characteristic, is built in the lens holder 20, and forms the lens block 19, and a position in an optical axis direction can be adjusted in the lens block.

The lens 2 is made of a resin material satisfying an optical characteristic, “Zeonex” commodity name manufactured by Nippon Zeon is used, for example, and realizes so-called pan focus capable of forming an image of a distant subject from a given distance. The lens holder 20 is provided with a diaphragm 3. The semiconductor image pickup device 4 and the optical filter 5 as a translucent member for limiting transmission of infrared light are placed on the pedestal section 7. These components are assembled on the stereoscopic board 1 with good accuracy.

The structure of the image pickup apparatus 8 will be discussed in more detail with reference to FIG. 2. FIG. 2 is a sectional view of the image pickup apparatus 8 taken on X-X in FIG. 1. A partition wall 11 is formed in the boundary between the pedestal section 7 and the lens-barrel section 17, an opening 10 is formed in the center of the partition wall 11, and upper and lower faces of walls surrounding the opening 10 form parallel flat planes. The optical filter 5 is placed on the flat plane on the lens side of the opening 10 and the semiconductor image pickup device 4 is placed on an opposite plane. The opening 10 is formed as a rectangle corresponding to the image pickup area of the semiconductor image pickup device 4. The pedestal section 7 is formed on the back with a wiring pattern 7c by electroless plating, etc., to bare-mount the semiconductor image pickup device 4. The wiring pattern 7c is electrically connected to the terminal part 7a by a pattern.

The semiconductor image pickup device 4 adopts Bayer arrangement of square pixels each having a pixel size of 2.25 μm. Peripheral circuitry containing an OB (Optical Black) block, an ADC, a TG (Timing Generator), etc., is provided in the surrounding of the effective range light reception portion of light reception and a bare chip of CMOS called ¼-inch UXGA type having about 2,000,000 pixels is flip-flop mounted by SBB (Stud Bump Bond), BGA (Ball Grid Array), etc. After the semiconductor image pickup device 4 is bare-mounted, it is adhered and sealed with a sealing compound 9.

A video signal provided by the semiconductor image pickup device 4, an external control signal, and electric power are supplied via the wiring pattern 7c and the connection land 15a of the FPC 15. To prevent entry of visible light and infrared light from the back of the FPC 15 into the semiconductor image pickup device 4, metal foil 14 is put on the back of the FPC 15.

The optical filter 5 as a translucent member has a glass substrate having a thickness of 0.3 mm to which an IR (InfraRed) cut coat is applied. The IR cut coat is given a required spectral characteristic as a transparent dielectric film of silicon dioxide (SiO₂), titanium oxide (TiO₂), magnesium fluoride (MgF₂), zirconium dioxide (ZrO₂), etc., is formed by evaporation.

Next, the operation of the image pickup apparatus 8 will be discussed. Light from a subject passes through the diaphragm 3, is gathered through the lens 2, and is made incident on the optical filter 5, and unnecessary infrared light and ultraviolet light are limited. The light passing through the optical filter 5 is incident on the semiconductor image pickup device 4, passes through a known lens called a microlens or an on-chip lens not shown, passes through a color filter of a pigment system existing below the lens, and is converted into a required electric signal by a photodiode. The signal is output as an image signal at a frame rate of 15 frames per second with the screen aspect ratio being 4:3 and is output via the wiring pattern 7c of the pedestal section 7 from the terminal part 7a on the outside of the pedestal section 7 through the FPC 15 to an external monitor, etc.

Next, “flaw” and “stain” caused by dust of the invention will be discussed. In the image pickup apparatus 8, a black spot, a white spot, etc., of an image caused by a defect of the semiconductor image pickup device 4 or dust deposited on the surface of the semiconductor image pickup device 4 is commonly named “flaw.” If dust is deposited or put on the light reception surface of the semiconductor image pickup device 4, entry of light is inhibited in pixel units. Even if dust is optically transparent SiO₂, etc., entry of light is inhibited because of the refractive index difference from air. That is, for the flaw, the effect of incident light is given by dust as if a bandage were put in pixel units and thus output of the target pixel obviously changes relative to the surrounding pixels. The periphery of the dust is clearly seen because of large change in pixel units. Therefore, when a picked-up image is seen, obviously clear recognition can be made in pixel units.

On the other hand, dust positioned at a distance of about 0.2 to 0.5 mm or more, for example, from the semiconductor image pickup device 4 is at an out-of-focus position of the lens 2 and causes lowering of a light flux so as to cast a shadow on the semiconductor image pickup device 4. It is known that generally the shadow produces a dark umbra in the center and a bright penumbra in the surrounding of the umbra. Thus, the shadow caused by dust causes image degradation of a very unclear feeling because the periphery of the dust blurs unlike a flaw. Image degradation of unclearness causing lowering of a light flux so as to cast a shadow on the semiconductor image pickup device 4 without directly covering the light reception face of the semiconductor image pickup device 4 is called “stain” distinguished from the flaw. For the stain, experiment was repeated using several types of image pickup apparatus and it turned out that stain cannot be recognized unless there is an intensity difference of about 5% or more from the periphery when a white subject is photographed. In other words, it is considered that stain does not occur if dust does not have a size to such an extent that a light flux is lowered 5% or more.

Based on this point of view, a concept of the relationship between dust and a decrease in a light flux caused by stain occurrence will be discussed with FIG. 3. Now, let the area of the light flux orthogonal to the optical axis at the incidence position of the lens (corresponding to the portion of the diaphragm 3), that in the image formation face (light reception face of the semiconductor image pickup device 4), and that at a location positioned therebetween be S, S₀, and S′ respectively. If it is simply assumed that dust is a completely black body having light transmittance of 0 and that the light flux is uniform, the area of dust for lowering the light quantity 5% as described above relative to the area of the light flux corresponds to 5% of the S, S₀, S′ area. More precisely, it is assumed that the size of dust indicates the projection area in the optical axis direction. Since the area of the light flux has the relationship of S>S′>S₀ in the image pickup apparatus, it is understood that larger dust would become stain as it is more distant from the light reception face of the semiconductor image pickup device 4. This means that even small dust causes stain as it is nearer to the semiconductor image pickup device 4.

A flaw correction can be made using ambient pixels of the semiconductor image pickup device 4, as described in patent document 3 described above. However, since the periphery of stain blurs as described above, if a correction is made based on the shading characteristic, it is very difficult to make a correction to stain; basically any measure other than exclusion of dust is ineffective. In the embodiment, the distance from the light reception face of the semiconductor image pickup device 4 to the lower face of the optical filter 5 is 0.56 mm and the thickness of the optical filter 5 is 0.3 mm. The lens 2 has F4 as the F number indicating the brightness and has a focal length of 3.7 mm. When dust was made globular to lower the light flux 5% and the diameter of dust was roughly calculated, the following result was obtained: Considering the possibility that dust may be deposited on the light reception face of the semiconductor image pickup device 4, stain is caused by dust of a size of 2.25 μm equal to the pixel size or more in the space range from the light reception face of the semiconductor image pickup device 4 to the lower face of the optical filter 5. In this case, in fact, dust appears as a flaw because it acts so as to put a bandage on a pixel. Stain is caused by dust of about 30 μm or more if the dust does not fall on to the light reception face of the semiconductor image pickup device 4 in the lower face of the optical filter 5. Stain is caused by dust of about 45 μm or more in the upper face of the optical filter 5; stain is caused by dust of about 70 μm or more in the lower face of the lens 2 (the lower face of the lens 2b). Stain is caused by dust of about 200 μm or more at the position of the diaphragm 3 most distant from the semiconductor image pickup device 4. When the values were found about several similar types of image pickup apparatus, mostly similar values were found.

That is, in the space in which the semiconductor image pickup device 4 is housed, there is a possibility that dust may be deposited on the light reception face of the semiconductor image pickup device 4, and thus dust of a size equal to or more than the pixel size needs to be excluded. Since dust of this order of size floats and is hard to fall, it is understood that it is important and effective to assemble in a clean room. Particularly in assembling the semiconductor image pickup device 4, it is also important to improve the cleanness of the working environment, enhance cleaning, aggressively exclude static electricity with an ionizer, etc.

Next, FIG. 4 shows the result of examining the effect on the image quality with dust actually contained into the image pickup apparatus 8. In FIG. 4, portions of the image pickup apparatus 8 are indicated on the horizontal axis according to the distance from the semiconductor image pickup device 4, and allowable dust size is taken on the vertical axis. As a checking method, the image pickup apparatus 8 is exposed in an atmosphere in which spherical dust with a broad particle size distribution is circulated and then dust that can be determined stain from the image is disassembled according to the position, the size, etc., and the size is examined under a microscope. The portions of the image pickup apparatus 8 and dust observed as stain are marked with X and dust not observed as stain is marked with . The boundaries between X and are connected smoothly. According to this, it is understood that the size becomes equal to the pixel size in the space in which the semiconductor image pickup device 4 is housed and that the allowable size grows in proportion to the distance from the semiconductor image pickup device 4 from the upper face of the optical filter 5.

Based on the point of view of stain occurrence and the experimental result, capture of dust in the image pickup apparatus 8 will be discussed with FIGS. 5 and 6. FIG. 5 is a sectional view to show applying positions of an adhesive, and FIG. 6 is a sectional view to describe an applying method of an adhesive. Adhesives 6 and 6A are applied to the surface of the stereoscopic board 1 on the outside of the space surrounded by the semiconductor image pickup device 4, the optical filter 5, and the stereoscopic board 1 to form an adhesive area. This portion is outside the optically effective range and dust captured in the portion does not affect the image quality. The adhesive 6 mainly aims at dust moving from the lens 2, and the adhesive 6A aims at dust entering from the lens-barrel section 17 portion of the lens and the outside of the image pickup apparatus 8. An adhesive 6B can also be used for applying to the outside of the optically effective range in the upper face of the optical filter 5 as required. Further, it is obvious that adhesive may be applied to the corresponding portion of the lens barrel. Dust floats and moves in the spaces and thus can be captured outside the optically effective range. Capture of dust in the optically effective range is not preferred because the dust is left as stain for an indefinite time and degrades the quality of the image pickup apparatus.

As each adhesive in the embodiment, an adhesive provided by dissolving acrylic resin in a volatile solvent having fluorine such as 1,3-bistrifluorobenzene or hydrofluorocarbon was used. It is desirable that the ratio between the acrylic resin and the solvent should be selected as required while adsorption of dust is evaluated; setting the upper limit of the resin to about 10 wt % led to a good result. Although any other resin and solvent may be used and can be selected as required, so strong adhesion is not needed because it is the case of capturing dust. This is because that if it is assumed that the particle size (diameter) of dust to be captured is 50 μm and that the density is about 7, the mass is small as 0.5 μgr at most. The viscosity as a solution should be smaller so that the solution can penetrate even a small gap; preferably the viscosity is about 0.01 Pa·S or less and more preferably is about 0.001 Pa·S of the same order as water. The viscosity can be selected as required according to the penetration range, the gap size, the temperature of the working environment, etc.

Applying of a solution 23 containing an adhesive will be discussed with reference to FIG. 6. As a method of applying the solution to a required part, the solution can be applied with a brush, can be transferred by a stamp, or can be applied with an injector or a dispenser, but has fluorine in a solvent of resin as described above. Fluorine has very poor adhesion because of surface energy and is known as a material hard to adhere. Therefore, the solution needs to be applied with extreme caution so that the solvent is not deposited on the portion to adhere to. Thus, incidental work of masking, wiping off, removal, etc., occurs. Further, if sufficient wiping off is performed, the possibility that the adhesive strength may be degraded due to slightly remaining fluorine is left. Then, the lens block 19 is adhered and fixed to the stereoscopic board 1 with an adhesive agent 25. After this operation, the solution 23 containing an adhesive is injected through an injection part 12 by injection means 22.

Next, the applying method will be discussed in more detail with reference to FIG. 7. FIG. 7 (a) is a plan view of viewing the stereoscopic board 1 from the lens side, and the solution 23 containing an adhesive is injected through the injection part 12 by the injection means 22. The solution 23 containing an adhesive injected through the injection part 12 spreads up and down to corners as indicated by arrows in the figure because of a capillary phenomenon in a gap 24 of the area portion shaped like a quadrangular belt indicated by the dashed line provided between the stereoscopic board 1 and the lens base 21 and then spreads in the left direction. FIG. 7 (a) shows a state in which the solution is injected through the injection parts 12 provided at the left and the right. According to this, the solution 23 containing an adhesive can be applied almost over the total circumference of the stereoscopic board 1. First, one part is adhered and fixed with the adhesive agent 25 in the center portion of each of the two opposed sides of the peripheral portions of the lens base 21 of the lens block 19 and the stereoscopic board 1. An epoxy-based adhesive agent of UV curing type is used as the adhesive agent 25. The viscosity is about 5Pa·S like the viscosity of mayonnaise. The adhesive agent has a thixo property for suppressing entry from the peripheral portions of the lens base 21 and the stereoscopic board 1 through a gap into the inside. The viscosity, etc., can be selected as required according to the material, shape surface property, penetration range, etc., of the stereoscopic board 1 and the lens base 21 to be adhered. Thus, the lens block 19 and the stereoscopic board 1 are fixed by adhering. The injection part 12 having a larger opening than the gap 24 to inject the adhesive provided on the end face of the lens base 21 of the lens block 19 between the lens base 21 and the stereoscopic board 1 is provided on a side different from the side adhered with the above-described adhesive agent 25. Through the injection part 12, the solution 23 containing an adhesive is filled by the injection means 22 while using a capillary phenomenon of the gap 24 between the lens base 21 and the stereoscopic board 1.

The stereoscopic board 1 and the injection part 12 have a gap to allow air to circulate. FIG. 7 (b) is a main part enlarged view of FIG. 7 (a). For easy understanding, FIG. 7 (a) draws a larger gap than the actual one.

The gap 24 is formed by giving surface roughness of about ten and several μm to the surface of the face of the lens base 21 adhered to the stereoscopic board 1 between the lens base 21 and the stereoscopic board 1. Surface roughness is thus given to form the gap 24 on the lens base 21 side of the lens block 19, whereby it is not necessary to change the stereoscopic board 1 with respect to the specifications of various lenses, so that it is made possible to share the stereoscopic board 1 and it is advantageous for an increase in the product types. Although similar work can also be performed on the stereoscopic board 1 side, the lens base 21 is also created likewise for different lens block 19 and thus the shape, surface roughness, etc., more appropriate for adhesion and an adhesive is easy to optimize and the substance for change can be realized by the lens block 19, so that flexibility of design can be increased

The gap 24 provided on the lens base 21 side may be provided in the stereoscopic board 1 and alternatively may be provided in both faces. The surface roughness is created at the same time at the molding time with a texture added to a mold used to mold the lens base 21. FIG. 7 (b) shows a state in which the gap 24 is formed by roughing the face with texture. FIG. 7 (b) is an enlarged view of the cross section taken on Y-Y in FIG. 7 (a). In FIG. 7 (b), texture is provided on the lens base 21 side relative to the stereoscopic board 1. It can be understood that the almost flat stereoscopic board 1 and the texture provided on the lens base 21 form the gap 24. The roughness of the gap 24, etc., can be selected as required according to the spread, the applying amount of the solution, etc. As described above, the gap provided by texture is not filled by applying the adhesive agent 25 and thus the solution 23 containing an adhesive is injected and is diffused by surface tension and then the solvent volatilizes and the adhesive remains on the surfaces of the lens base 21 and the stereoscopic board 1 as indicated by the dotted line in FIG. 7 (b), making it possible to capture dust as a film having adhesion. Since the adhesive is thus applied after lens assembling with the adhesive agent, it is made possible to eliminate the effect of adhesion of fluorine contained in the solvent of the adhesive, and degradation of the adhesive strength between the lens base 21 and the stereoscopic board 1 can be prevented. Since masking, etc., is not needed, workability can be improved and production can be made efficient. Accordingly, dust dropping off from the lens periphery floats and moves to the gap 24 given adhesion, whereby it is made possible to capture the dust. It is also considered that external entered dust passes through the gap 24 and arrives at the optically effective range and thus it is also made possible to capture the entered dust.

In this way, in the embodiment, the gap may be formed using texture, and alternatively a groove may be previously formed.

Next, the assembling order of the image pickup apparatus 8 will be discussed with reference to the flowchart of FIG. 8. To begin with, a lens 2, a semiconductor image pickup device 4, an optical filter 5 as a translucent member, and a stereoscopic board 1 are provided (S101). Before assembly, electricity of the components is eliminated with an ionizer to prevent electrostatic deposition of dust. Ultrasonic cleaning is performed as required.

Next, the optical filter 5 as a translucent member is mounted on the stereoscopic board 1 (S102). After the optical filter 5 is set on the stereoscopic board 1, a required amount of an epoxy-based adhesive agent of thermosetting type is applied to the surrounding of the optical filter 5 with a dispenser, etc. As the step is executed, the stereoscopic board 1 is adhered to the optical filter 5 and the strength is enhanced, so that the stability of mounting in (Stud Bamp Bonding) or BGA (Ball Grid Array) is also enhanced in the slim image pickup apparatus.

Subsequently, the semiconductor image pickup device 4 is mounted according to SBB or BGA (S103). After the semiconductor image pickup device 4 is mounted, a required amount of a sealing compound of UV+thermosetting type is applied while irradiating from the direction of the optical filter 5 by a black light not shown. Accordingly, a bank to prevent the sealing compound from protruding to the effective range of the semiconductor image pickup device 4 is produced and vignetting, etc., is prevented.

Subsequently, a step of mounting the lens (S104) is executed, whereby assembling the image pickup apparatus is complete. As the image pickup apparatus, inspection of dust may be executed before the lens is assembled, or may be executed after the lens is assembled. After the steps to lens assembling are executed in a highly clean room, the lens assembling may be completed in an environment in which the cleanness is lowered to some extent. The steps can be changed as required depending on the image pickup apparatus.

Next, a solution 23 containing an adhesive is injected through an injection part 12 by injection means 22 provided in the surrounding of the stereoscopic board 1 (S105). The solution 23 containing an adhesive is spread in a gap by a capillary phenomenon, the solvent volatilizes, and the applying is complete. Since the solvent of the adhesive volatilizes and the applying is complete as described above, the workability is good and continuous process rather than batch treatment can be executed.

Since the adhesive is applied after the lens assembling with the adhesive agent, it is made possible to eliminate the effect of adhesion of fluorine contained in the solvent of the adhesive, and degradation of the adhesive strength between the lens base 21 and the stereoscopic board 1 can be prevented. Since masking, etc., is not needed, it is made possible to improve workability and production can be made efficient.

In the image pickup apparatus 8 assembled by executing the steps, a flaw and dust causing a flaw can be decreased reliably and occurrence of stain can be prevented because of the effect of the adhesive.

### Second Embodiment

Next, a manufacturing method of an image pickup apparatus according to a second embodiment of the invention will be discussed. In the first embodiment described above, an adhesive is filled after the lens is mounted; in the second embodiment, a method of mounting a lens after applying an adhesive to a board will be discussed.

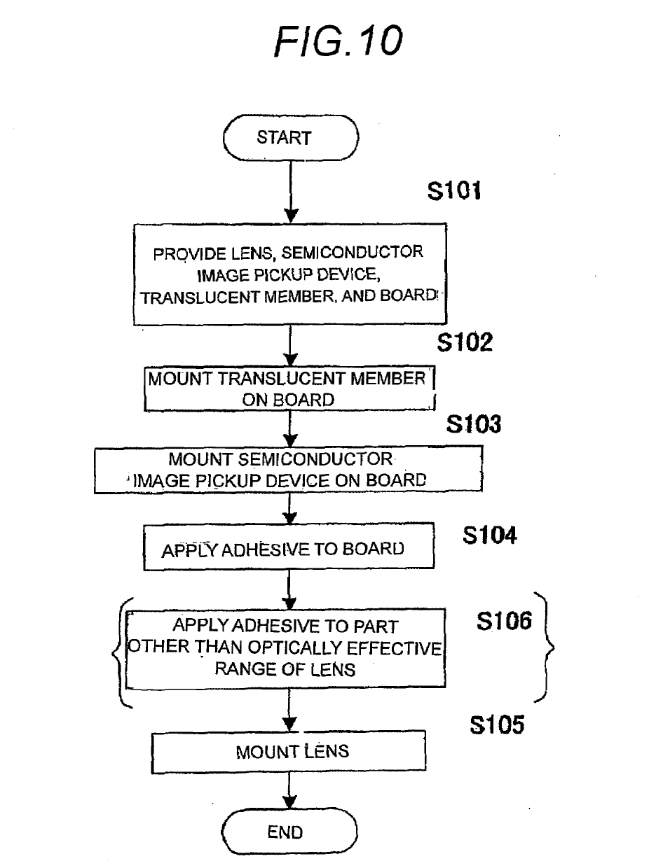

Prior to the description, FIG. 10 shows the result of examining the effect on the image quality with dust actually mixed into an image pickup apparatus 8 according to a different method from that of the embodiment described above. In FIG. 10, portions of the image pickup apparatus 8 are indicated on the horizontal axis according to the distance from a semiconductor image pickup device 4, and allowable dust size is shown by a chain double-dashed line on the vertical axis. On the other hand, the line indicated as a dashed line in the figure shows the allowable size when it is assumed that dust of the lens portion falls on to the upper face (the effect degree is high) of an optical filter 5.

As a checking method, the image pickup apparatus 8 is exposed in an atmosphere in which spherical dust with a broad particle size distribution is circulated and then dust that can be determined stain from the image is disassembled according to the position, the size, etc., and the size is examined under a microscope. The portions of the image pickup apparatus 8 and dust observed as stain are marked with X and dust not observed as stain is marked with . The boundaries between X and are connected smoothly. According to this, it is understood that the size becomes equal to the pixel size in the space in which the semiconductor image pickup device 4 is housed and that the allowable size grows in proportion to the distance from the semiconductor image pickup device 4 from the upper face of the optical filter 5. If it is assumed that the dust of the lens portion finally falls on to the upper face of the optical filter 5, it is considered that the characteristic becomes a characteristic indicated by the dashed line in the figure.

Thus, it is advantageous if the position of the optical filter 5 is brought close to the semiconductor image pickup device 4 as much as possible and the optical filter 5 is as thick as possible. In this case, the whole thickness of the image pickup apparatus increases and thus a good balance range exists. Considering the thickness to form a partition wall 10 of a stereoscopic board 1, the bump height to execute SBB-mount, etc., and as a result of examining a similar image pickup apparatus, preferably a length (gap) L between the semiconductor image pickup device 4 and the optical filter 5 is in the range of about 0.3 mm to about 0.8 mm and more preferably, in the range of 0.4 mm to 0.6 mm or so. It is also obvious from the analysis of the image pickup apparatus that a thickness t of the optical filter 5 may be in the range of 0.15 mm to 0.6 mm or so. To use a glass base material, it was found that more preferably the thickness of the filter 5 may be in the range of 0.2 mm to 0.4 mm.

The base material of the optical filter 5 is parallel and flat, but has a slight wave. On the other hand, the area of a light flux is smaller as closer to the semiconductor image pickup device 4. Accordingly, the incident light on the optical filter 5 has a spread because of the wave. Therefore, it is known that the resolution of a picked-up image is less degraded as the position of the optical filter 5 is closer to the semiconductor image pickup device 4 optically. In addition, it was found by repeating an experiment that preferably the range of L and t to make it possible to slim down the whole of the image pickup apparatus 8 is 1.0≦(L/t)≦2.5 or so.

Next, the assembling order of the image pickup apparatus 8 in the manufacturing method of the image pickup apparatus according to the embodiment of the invention will be discussed with reference to the flowchart of FIG. 10. To begin with, a lens 2, a semiconductor image pickup device 4, an optical filter 5 as a translucent member, and a stereoscopic board 1 are provided (S101). Prior to assembly, electricity of the components is eliminated with an ionizer to prevent electrostatic deposition of dust. Ultrasonic cleaning is performed as required.

Next, the optical filter 5 as a translucent member is mounted on the stereoscopic board 1 (S102). After the optical filter 5 is set on the stereoscopic board 1, a required amount of an epoxy-based adhesive agent of thermosetting type is applied to the surrounding of the optical filter 5 with a dispenser, etc. As the step is executed, the stereoscopic board 1 is adhered to the optical filter 5 and the strength is enhanced, so that the stability of mounting in (Stud Bamp Bonding) or BGA (Ball Grid Array) is also enhanced in the slim image pickup apparatus.

Subsequently, the semiconductor image pickup device 4 is mounted according to SBB or BGA (S103). After the semiconductor image pickup device 4 is mounted, a required amount of a sealing compound of UV +thermosetting type is applied while irradiating from the direction of the optical filter 5 by a ultraviolet light not shown. Accordingly, a bank to prevent the sealing compound from protruding to the effective range of the semiconductor image pickup device 4 is produced and vignetting, etc., is prevented.

Next, an adhesive is applied to required portions of the stereoscopic board 1 (S104). Concurrently with this step, an adhesive is applied outside the optically effective range of the lens as required. Since the solvent of the adhesive volatilizes and the applying is complete as described above, the workability is good.

Next, a step of mounting the lens (S105) is executed, whereby assembling the image pickup apparatus is complete.

As the image pickup apparatus, inspection of dust may be executed prior to the lens is assembled, or may be executed after the lens is assembled. After the steps to lens assembling are executed in a highly clean room, the lens assembling may be completed in an environment in which the cleanness is lowered to some extent. The steps can be changed as required depending on the image pickup apparatus.

In the embodiment described above, applying an adhesive to form an adhesive area is realized by applying to the board 1 prior to attaching the lens (lens block), but an adhesive may be applied to or filled into the abutment area of the lens block and the board 1 (S106) to form an adhesive area before or after attaching the lens block. Step S106 may be executed together with step S104 of applying an adhesive to the board prior to mounting the lens block or may be executed solely. The shapes of a lens holder and the lens making up the lens block can be changed as required.

In the embodiment, using the stereoscopic board 1, the semiconductor image pickup device is installed on one face and the translucent member is mounted on an opposite face, but they may be placed on the same face and the board is not limited to a stereoscopic board and a flat board may be used, needless to say.

The image pickup apparatus is assembled according to the embodiment, whereby a flaw and dust causing a flaw can be decreased reliably and occurrence of stain can be prevented because of the effect of the adhesive.

### Third Embodiment

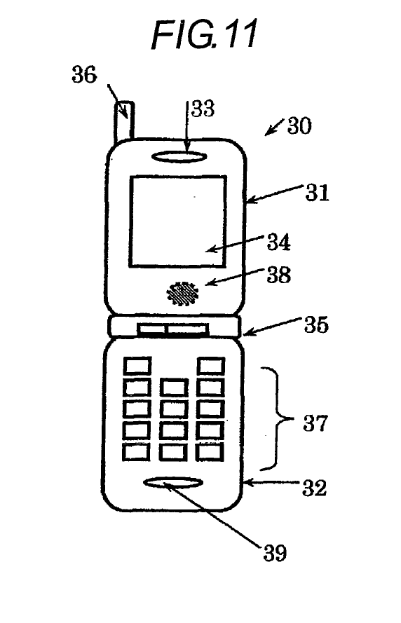

FIG. 11 is a plan view of a mobile telephone 30 using the image pickup apparatus 8 of the first embodiment of the invention. A third embodiment is an example of installing the image pickup apparatus in a folding mobile telephone 30. Particularly, miniaturization and improvement of convenience are realized. In FIG. 11, the mobile telephone 30 has an upper housing 31 and a lower housing 32 that can be folded through a hinge 35. A liquid crystal display screen 34, a loudspeaker 33, an antenna 36 for transmission and reception, an image pickup apparatus 38, and the like are installed in the upper housing 31. A microphone 39, input keys 37, etc., are installed in the lower housing 32. The image pickup apparatus 38 adopts the image pickup apparatus 8 of the first embodiment of the invention. The image picking up direction of the image pickup apparatus 38 is vertical to the plane of FIG. 7. To use the mobile telephone, the upper housing 31 and the lower housing 32 are opened; not to use the mobile telephone, the upper housing 31 and the lower housing 32 are folded.

A drop test was conducted with the image pickup apparatus 38 according to the first embodiment mounted in a mobile telephone. An experiment of dropping the mobile telephone to a concrete floor from a height of about 1.5 m 10 times and examining change in the quality of a picked-up image was conducted. The dropping direction was the lower side and the upper side in the optical axis direction. As a result, neither occurrence of stain nor an increase having the substantial effect on the quality of a picked-up image can be found before and after dropping 10 times. Image degradation was not found either after the image pickup apparatus 8 was exposed in the above-described atmosphere in which dust was circulated. When the apparatus was disassembled and was observed, deposition of dust was observed in the portion of the adhesive 6A applied to the shoulder portion of the stereoscopic board 1. Accordingly, it is considered that entry of dust can be prevented and the effect of suppressing occurrence of stain is exerted.

Accordingly, occurrence of stain caused by dust and degradation of the image quality in the mobile telephone can be prevented and reliability can be improved. The mobile telephone of the invention is not limited to the configuration and the invention can be applied to various mobile information apparatus. For example, it is obvious that the invention can be applied to mobile information apparatus of a PDA (personal digital assistant), a personal computer, an external machine of a personal computer, etc.

### INDUSTRIAL APPLICABILITY

In the image pickup apparatus of the invention, adhesion can be given to the portion outside the optically effective range on the outside of the space surrounded by the semiconductor image pickup device, the translucent member, and the board so as to capture dust causing stain for preventing degradation of the image quality; it is useful for an image pickup apparatus and camera application installed in a mobile terminal of a mobile telephone, etc.

1. An image pickup apparatus,
wherein a semiconductor image pickup device is installed on a board, and a translucent member and a lens are disposed with a spacing of an optical space within an image pickup area of the semiconductor image pickup device, and
wherein a gap to allow an adhesive-contained liquid to penetrate is provided outside a space surrounded by the semiconductor image pickup device, the translucent member and the board in the optical space, so that an adhesive area can be formed outside an optically effective area where an image can be picked up in the image pickup area.

2. The image pickup apparatus as claimed in claim 1,
wherein the semiconductor image pickup device is mounted on one face of the board, and the translucent member is mounted on the other face of the board, and in addition, a lens block carrying the lens is placed on the board with a predetermined spacing from the translucent member, and
wherein the gap to allow the adhesive-contained liquid to penetrate is provided in an interface between the board and the lens block.

3. The image pickup apparatus as claimed in claim 2,
wherein the gap includes an injection part having a larger opening than the gap to inject the adhesive-contained liquid.

4. The image pickup apparatus as claimed in claim 1,
wherein the adhesive area is formed of an applied film containing an adhesion component.

5. The image pickup apparatus as claimed in claim 1,
wherein the adhesive area is formed at least in a part of the area surrounding the optically effective area where the image can be picked up, in the image pickup area outside the space surrounded by the semiconductor image pickup device, the translucent member and the board in the optical space.

6. The image pickup apparatus as claimed in claim 5,
wherein the semiconductor image pickup device is mounted on one face of the board and the translucent member is mounted on the other face of the board, and
wherein in addition, a lens block carrying the lens is placed on the board with a predetermined spacing from the translucent member.

7. The image pickup apparatus as claimed in claim 5,
wherein the adhesive area is formed of an applied film containing an adhesion component.

8. The image pickup apparatus as claimed in claim 2,
wherein the adhesive area is disposed at least in a part of an abutment area of the lens block with the board.

9. The image pickup apparatus as claimed in claim 8,
wherein the adhesive area is disposed in a whole circumference surrounding the semiconductor image pickup device, of the abutment area of the lens block with the board.

10. The image pickup apparatus as claimed in claim 8,
wherein the adhesive area is provided at a position inward by a predetermined width from an outer end of the board and is disposed along an outer periphery of the board.

11. The image pickup apparatus as claimed in claim 2,
wherein the adhesive area is formed by filing the adhesive-contained liquid into a recess part provided in the board or the lens block.

12. The image pickup apparatus as claimed in claim 1,
wherein the translucent member is an optical filter of a layered product of a plurality of dielectrics.

13. The image pickup apparatus as claimed in claim 1,
wherein the board is a stereoscopic board having a placement part for placing the semiconductor image pickup device thereon.

14. The image pickup apparatus as claimed in claim 1,
wherein the lens, the translucent member, the board, and the semiconductor image pickup device are placed in this order from a subject side along an optical axis, and the adhesive area is formed at least in a part of an abutment area of the lens with the translucent member.

15. The image pickup apparatus as claimed in claim 2,
wherein the adhesive area is an area for fixing the lens block to the board.

16. A manufacturing method of the image pickup apparatus recited in claim 1, the manufacturing method comprising the steps of:
providing the lens, the semiconductor image pickup device, the translucent member, and the board; and
mounting the translucent member, the semiconductor image pickup device, and the lens on the board.

17. The manufacturing method of the image pickup apparatus as claimed in claim 16, comprising:
a step of filling the adhesive-contained liquid into the gap so as to surround the optically effective area where the image can be picked up in the image pickup area outside the space surrounded by the semiconductor image pickup device, the translucent member and the board, after the step of mounting the lens.

18. The manufacturing method of the image pickup apparatus as claimed in claim 17, comprising the steps of:
providing a lens block incorporating the lens, the semiconductor image pickup device, the translucent member, and the board;
mounting the translucent member and the semiconductor image pickup device on the board;
mounting the lens block on the board; and
penetrating the adhesive-contained liquid into the gap between the board and the lens block.

19. The manufacturing method of the image pickup apparatus as claimed in claim 18,
wherein the penetrating step includes a step of filling into the gap a solution in which an adhesive is dissolved in a volatile solution.

20. The manufacturing method of the image pickup apparatus as claimed in claim 19,
wherein the penetrating step includes a step of filling and penetrating the solution from two opposed directions.

21. The manufacturing method of the image pickup apparatus as claimed in claim 16,
wherein the image pickup apparatus is assembled by executing a step of applying an adhesive to the board and a step of mounting the lens after the step of mounting the semiconductor image pickup device on the board.

22. The manufacturing method of the image pickup apparatus as claimed in claim 21, comprising:
a step of applying an adhesive on a part other than an optically effective range of the lens prior to the step of mounting the lens.

23. A mobile terminal adopting the image pickup apparatus as claimed in claim 1.

24. A mobile terminal adopting the image pickup apparatus manufactured by the manufacturing method of the image pickup apparatus as claimed in claim 1.
